(19) United States
(12) Patent Application Publication
(10) Pub. No.: US 2003/0047796 A1
(43) Pub. Date: Mar. 13, 2003

(54) Narrow channel field effect transistor and method of making the same

(76) Inventors: Zhenan Bao, Jersey City, NJ (US); Robert William Filas, Bridgewater, NJ (US); Peter Kian-Hoon Ho, North Plainfield, NJ (US); Jan Hendrik Schon, Summit, NJ (US)

Correspondence Address: Docket Administrator (Room 3J-219), Lucent Technologies Inc., 101 Crawfords Corner Road, Holmdel, NJ, 07733-3030, US

(21) Appl. No.: 09/951,055

(22) Filed: Sep. 13, 2001

(51) Int. Cl. H01L 23/58

(52) U.S. Cl. 257/632

(57) ABSTRACT

A method for making an apparatus, for example, comprises attaching at least one self-assembled monolayer to a first element formed on a substrate. Thereafter, at least one attaching layer is formed on the substrate, adjacent to the one or more self-assembled monolayers. A second element is then formed on the one or more attaching layers spaced from the first element by about a length of the one or more self-assembled monolayers.

### FIELD OF THE INVENTION

The invention relates to semiconductor devices.

### BACKGROUND OF THE INVENTION

A field effect transistor (“FET”) has an active channel, formed within a layer of semiconductor material, as well as a drain and a source electrode. The active channel has a conductivity that is responsive to an electric field applied from a gate electrode through a gate dielectric layer. Depending on the conductivity, a current may flow through the channel when a voltage is applied between the drain and source electrodes. Consequently, the voltage on the gate electrode derived from the electric field controls the amount of current flowing through the channel.

The channel width of a FET, defined by the distance separating the drain and source electrodes, corresponds with a number of performance characteristics of a FET. More particularly, a decrease in the dimensions of the channel facilitates an increase in the switching speed and frequency response characteristics of a FET. As such, considerable efforts have been expended in decreasing the spacing between the drain and source electrodes, and thusly, narrowing the channel.

Semiconductor devices and other nanotechnology elements are presently manufactured using a patterning technique commonly referred to as photolithography. Photolithography involves the use of a mask to impart a pattern onto a layer or substrate. The limitations of photolithography in scaling down semiconductor devices, including the distance separating the drain and source electrodes, for example, are now becoming a practical concern. As the semiconductor industry continues to scale down devices employing FETs, certain feature sizes of the desired patterns created by photolithographic masks may soon be limited by diffraction. Therefore, a method is needed for overcoming the limitations of photolithography to reduce the distance separating the drain and source electrodes, reduce the width of the channel, and increase the switching speed and frequency response characteristics of a FET.

### SUMMARY OF THE INVENTION

We have recognized that the distance separating the drain and source electrodes may be reduced by using an organic insulating molecule as a spacer. More particularly, we have invented a method for separating a first and second element using a mono-molecular layer, in contradistinction with a multi-molecular layer, as detailed in the known art. For the purposes of the present invention, the term mono-molecular layer, or monolayer means a single layer having a length of one molecule, wherein each atom of the monolayer has at least one chemical bond. Each of the first and second elements of the present invention may be realized by a conductive component, an insulative component, a semiconductive component, or a nanotechnology component, such as a micro-electromechancial system (“MEMS”) device. In our invention, a monolayer repels the formation of a second element on a previously formed first element. The monolayer moreover spaces the formation of the second element from the first element at about the length of the monolayer.

In one of several examples of the present invention, the monolayer repels a metalization layer from being disposed onto or in contact with a first conductive element in the formation of a second conductive element. Consequently, the monolayer spaces the second conductive element from the first conductive element by at about the length of the monolayer.

In another example of the present invention, an attaching layer is disposed adjacent to the monolayer for supporting the formation of and defining the location of the second element on a substrate. To facilitate the spacing between the electrodes, the monolayer may comprise hydrophobic properties, while the attaching layer may comprise hydrophilic properties.

In yet another example of the present invention, a first electrode of a transistor is separated from another electrode by at least one monolayer. Here, the monolayer may be self-assembled and may also comprise at least one organic insulating molecule. The monolayer is attached to the first electrode. The second electrode is formed at a distance of about the length of the monolayer—less than or equal to 15 nanometers—given the monolayer's propensity for repelling the formation of the second electrode from forming on the first electrode.

### BRIEF DESCRIPTION OF THE DRAWINGS

The present invention will be better understood from reading the following description of non-limiting embodiments, with reference to the attached drawings, wherein below:

FIG. 1(a) is a cross-sectional view of an embodiment of the present invention, while FIG. 1(b) depicts an exemplary feature of the embodiment of FIG. 1(a);

FIG. 2 is a cross-sectional view of an example embodying the principles of the present invention;

FIG. 3(a) and FIG. 3(b) are cross-sectional views of a field effect transistor undergoing a method embodying the principles of the present invention;

FIG. 4 is a flow chart to a method according to the principles of the present invention;

FIG. 5 is a flow chart to a method of making a field effect transistor according to the principles of the present invention;

FIG. 6 is a flow chart to another method of making a field effect transistor according to the principles of the present invention;

FIG. 7 is a flow chart to yet another method of making a field effect transistor according to the principles of the present invention; and

FIG. 8 is a graphical illustration of exemplary current (μA) versus gate electrode voltage (V) characteristics according to the principles of the present invention.

It should be emphasized that the drawings of the instant application are not to scale but are merely representations of the invention, which may be determined by one of skill in the art by examination of the information contained herein.

### DETAILED DESCRIPTION

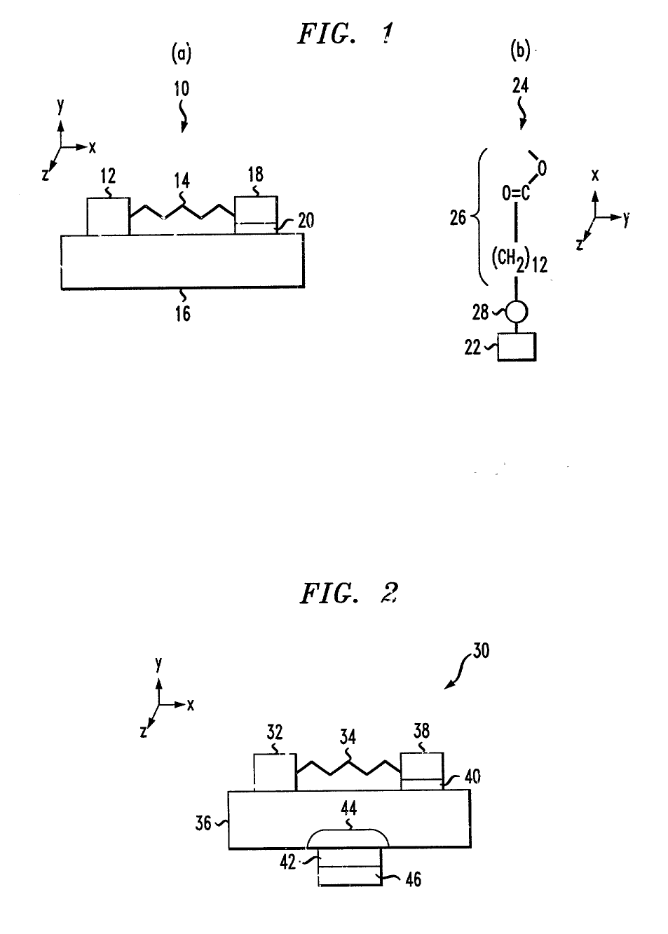

Referring to FIG. 1(a), a cross-sectional view of an embodiment of the present invention is illustrated. More particularly, an apparatus 10 is shown. Apparatus 10 comprises a first and a second element, 12 and 18. First and second elements, 12 and 18, are formed on a substrate 16 and may be realized by any combination of the following: a conductive component, an insulative component, a semiconductive component, or a nanotechnology component, such as a MEMS device. Other realizations requiring the formation of a second element in close proximity to a first element will become apparent to ordinary skilled artisans upon reviewing the instant disclosure.

In accordance with the present invention, apparatus 10 comprises at least one self-assembled monolayer 14. Monolayer 14 acts as a spacer in the fabrication of apparatus 10. More particularly, monolayer 14 causes the formation of second element 18 to be spaced from first element 12 at a distance of at about the length of monolayer 14—e.g., less than 15 nm. In one example of the present invention, the length of monolayer 14 and, thusly, the spacing between elements 12 and 18 is about two (2) nm.

Monolayer 14 repels second element 18 from forming onto the first element 12 during the fabrication of apparatus 10. To realize this function, monolayer 14 binds or attaches to first element 12 and is aligned in the direction of at least the x-axis. Depending on apparatus 10 and material composition of second element 12, monolayer 14 may have hydrophobic properties to repel the formation of second element 18 on first element 12. Consequently, monolayer 14 may space second element 18 from first element 12 at about its own length, given its repelling properties. It should be noted that monolayer 14 may be realized by at least one organic insulating molecule, though other compositions, such as a conducting molecule, a semiconducting molecule, or a combination thereof, for example, are contemplated hereby.

Apparatus 10 may also comprise an attaching layer 20. Attaching layer 20 supports the formation of second element 18 by defining its location on substrate 16. Attaching layer 20 is positioned adjacent to monolayer 14. As such, attaching layer 20 is disposed on portions of substrate 16 not covered by monolayer 14, thereby defining location of the second element 18.

Attaching layer 20 may have hydrophilic properties to facilitate the formation of second element 18 at a desired location on substrate 16, and at a defined distance (e.g., the length of monolayer 14) away from first element 12. Attaching layer 20 insures that the material employed in fabricating second element 18 need not cover the entire surface of substrate 16. Thusly, upon completing the fabrication of apparatus 10, a removal step for removing excess material in fabricating second element 18 is not necessary. Without such a removal step, monolayer 14 may be substantially short enough to space first and second elements, 12 and 18, in extremely close proximity to one another—as defined by the length of monolayer 14. It should be noted that attaching layer 20 might also have conductive properties for conductively coupling with substrate 16 with second element 18.

Upon completing the fabrication of apparatus 10, monolayer 14 may serve another functional purpose beyond that of acting as a spacing mechanism between elements 12 and 18. In certain applications and depending on the composition of monolayer 14, the continuing presence of monolayer 14 between first and second elements, 12 and 18, may enhance particular performance characteristics of apparatus 10, such as the breakdown voltage of a field effect transistor, for example. In the alternative, monolayer 14 may also be removed after second element 18 is formed.

Referring to FIG. 1(b), an exemplary molecular structure of monolayer 24 is shown, for use in a device, such as apparatus 10 of FIG. 1(a). Monolayer 24 comprises at least one organic insulating molecule 26.

Organic insulating molecule 26 attaches in an orthogonal manner to a first element 22, such as an electrode, for example. Thusly, organic insulating molecule 26 is normal to the surface of first element 22 in at least the direction of the x-axis.

Monolayer 24 also comprises an interfacial component 28. Organic insulating molecule 26 bonds with first element 22 by means of interfacial component 28. Sigma (σ) orbitals from organic insulating molecule 26 extend in the direction of the y-axis, between first element 22 and interfacial component 28. As such, electrical current is inhibited from flowing from first element 22 and through monolayer 24, thereby making organic insulating molecule 26 function as a directional insulator.

Interfacial component 28 may serve multiple functions as part of monolayer 24. Interfacial component 28 may also increase the bonding between organic insulating molecule 26 and first element 22. Moreover, interfacial component 28 may also increase the dielectric properties of monolayer 24 as viewed by first element 22.

Organic insulating molecule 26 may comprise an alkyl chain or tail, such as a tetradecyl-1-enyltrichlorosilane having its vinyl end groups oxidized to obtain —COOH terminations, which are thereafter, esterified with a pyrene methanol. In one example of present invention, monolayer 24 is formed from alkanethiol, wherein organic insulating molecule 26 comprises an alkyl chain and interfacial component 28 is sulfur. Advantageously, organic insulating molecule 24 comprises an alkyl chain having a linear or slightly branched, linear configuration. In the alternative, organic insulating molecule 24 may comprise a polyether chain, as well as other non-fully conjugated chains. Various additional substitutes, however, will be apparent to skilled artisans upon reviewing the instant disclosure.

Referring to FIG. 2, a semiconductor device 30 embodying the principles of the present invention is shown. Semiconductor device 30 is depicted as a particular field effect transistor (“FET”) configuration. However, other device configurations and types, including a bipolar junction transistor (“BJT”), for example, are also contemplated hereby.

FET 30 comprises a semiconductor layer 36. FET 30 comprises a gate dielectric layer 42, disposed between semiconductor layer 36 and a gate electrode 46. Semiconductor layer 36 comprises an active channel 44, as well as a source and a drain electrode, 32 and 38. Source and drain electrodes, 32 and 38, are spaced from one another by at least one self-assembled monolayer 34. Monolayer 34 causes the formation of one of electrodes, 32 and 38, to be spaced from the other electrode at a distance of at about the length of monolayer 34 (e.g., less than 15 nm), thereby defining the width of channel 44. In an example of the present invention, the spacing between electrodes, 32 and 38, is about two (2) nm, given the length of monolayer 34. Consequently, channel 44 may have a width of about two (2) nm.

Monolayer 34 repels one of electrodes, 32 and 38, from forming onto the other electrode during the fabrication of FET 30. In one example of FET 30, monolayer 34 repels drain electrode 38 from forming onto source electrode 32. Monolayer 34 binds or attaches to source electrode 32 and is aligned in the direction of at least the x-axis. Consequently, this repelling feature causes monolayer 34 to space drain electrode 38 from source electrode 32 at about the length of monolayer 34.

Monolayer 34 comprises at least one organic insulating molecule. The organic insulating molecule comprises insulating properties for insulating source electrode 32 from other conductive layers, generally, and more particularly, from drain electrode 38. Moreover, the organic insulating molecule also insulates channel 44, from drain electrode 38. This feature is attributable to the fact that monolayer 34 extends over and thereby covers channel 44.

FET 30 also comprises an attaching layer 40. Attaching layer 40 supports the formation of drain electrode 38 by defining its location on layer 36. Attaching layer 40 is positioned adjacent to monolayer 34. As such, attaching layer 40 is disposed on portions of layer 36 not covered by monolayer 34, thereby defining location of the drain electrode 38.

Attaching layer 40 has conductive properties for conductively coupling with layer 36 with drain electrode 38. Moreover, attaching layer 40 may also comprises hydrophilic properties to facilitate the formation of drain electrode 38 at a desired location on layer 36, and at a defined distance (e.g., the length of monolayer 34) away from source electrode 32. In this regard, the hydrophobic properties of monolayer 34 repels the formation of drain electrode 38 onto source electrode 32, and, in turn, attracts the formation of drain electrode 38 onto attaching layer 40, given its hydrophilic properties.

Attaching layer 40 insures that the material employed in fabricating drain electrode 38 need not cover the entire surface of layer 36. Thusly, upon completing the fabrication of FET 30, a removal step for removing excess material in fabricating drain electrode 38 may not be necessary. Without such a removal step, monolayer 34 may be substantially short enough to space electrodes, 32 and 38, in extremely close proximity to one another such that the width of channel 44 is correspondingly small.

Monolayer 34 may also serve an additional functional purpose beyond acting as a spacing mechanism between electrodes 32 and 38. The presence of monolayer 34 between source and drain electrodes, 32 and 38, may enhance particular performance characteristics of FET 30. In particular, the breakdown voltage of FET 30 may be substantially enhanced. However, in the alternative, monolayer 34 may be removed after drain electrode 38 is formed.

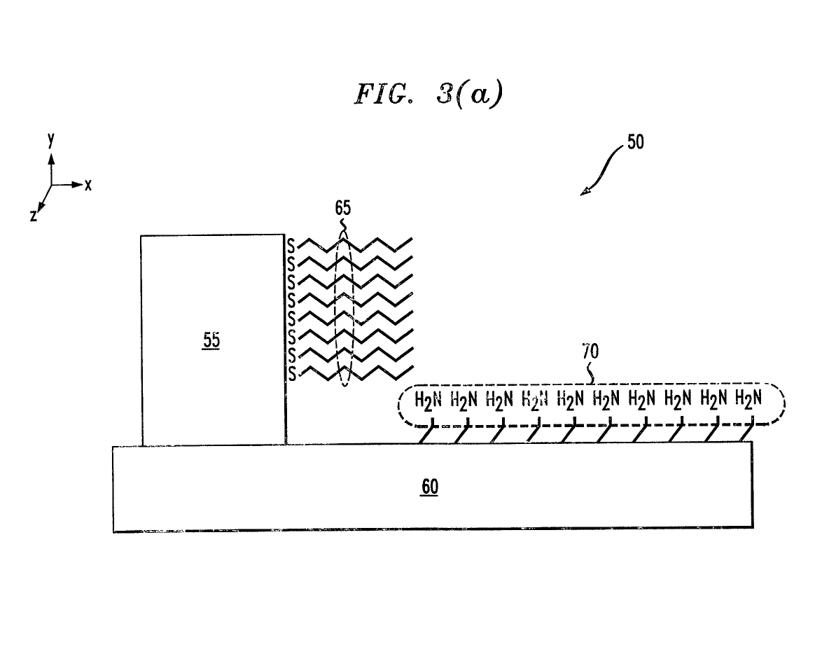

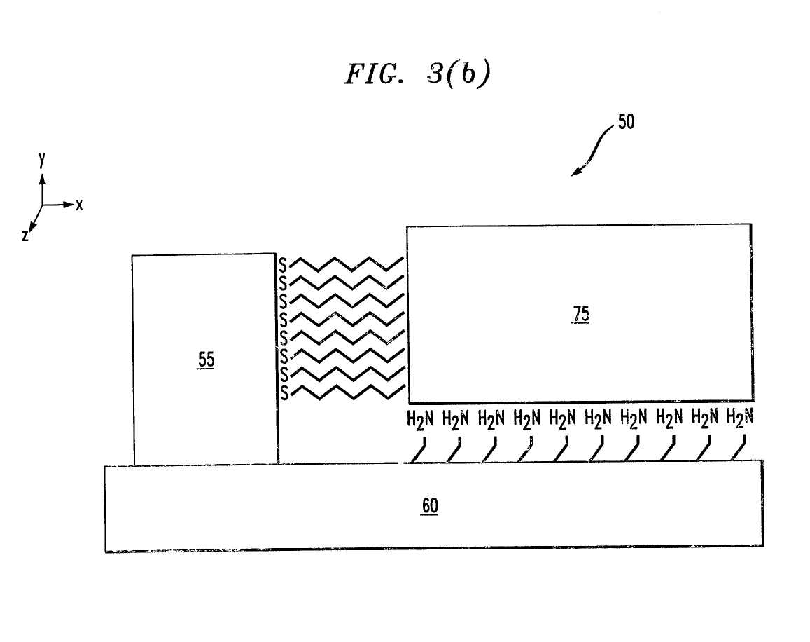

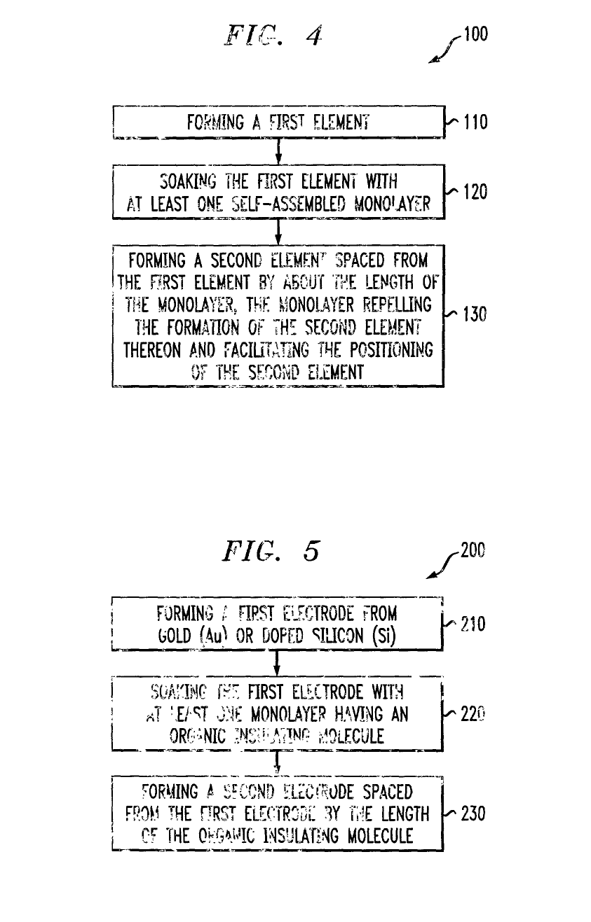

Referring to FIG. 3(a), a nanotechnological device 50 is shown undergoing a first step embodying the principles of the present invention. Device 50 comprises a substrate, base or layer 60. Layer 60 may comprise, for example, a semiconductor material, such as silicon, or a dielectric material, such as silicon dioxide.

Formed on layer 60 is a first conductive element or electrode 55. First electrode 55 may comprise any one of a number of conductive materials, including gold or doped silicon, for example. First electrode 55 may be formed on layer 60 by various process steps, including initially evaporating the conductive material onto layer 60, and thereafter patterning the evaporated conductive material to form first electrode 55.

Device 50 comprises a number of monolayers 65. Each monolayer 65 comprises a self-assembled organic insulating molecule, such as an alkyl chain, for example, and an interfacial component, such as sulfur. Each monolayer 65 attaches in an orthogonal manner to first electrode 55. Thusly, each monolayer 65 is normal to the surface of first electrode 55 on which it attaches itself. Monolayers 65 may be attached to first electrode 55 by soaking, rinsing, bathing or immersing layer 60 in an organic solution, such as alkanethiol, for example.

Device 50 also comprises a number of amino-functional molecules 70. In one example, amino-functional molecules 70 act as precursors for a subsequently formed attaching layer that enables layer 60 to be conductively coupled with a subsequently formed second element or electrode 75. Each amino-functional molecule 70 comprises nitrogen, is non-conductive and has chelating properties for binding with the surface of layer 60. Amino-functional molecules 70 may be attached by soaking, rinsing, bathing or immersing layer 60 in a solution comprising 1-amino-3propyl-triethoxy silane, for example. If substrate 60 comprises an oxide, it is advantageous to form amino-functional molecules 70 by exposing layer 60 to a vapor containing 1-amino-3-propyl-triethoxy silane. It will be apparent to skilled artisans that monolayers 65 may be attached to electrode 55 before or after amino-functional molecules 70 are attached to substrate 60.

Referring to FIG. 3(b), device 50 is shown undergoing a second method step embodying the principles of the present invention. Here, second electrode 75 is formed on some of amino-functional molecules 70. Prior to forming second electrode 75, layer 60 as processed in FIG. 3(a) is soaked, rinsed, bathed or immersed in a catalytic solution. The catalytic solution comprises catalytic ions, such as Pd²⁺, for example, within hydrochloric acid. Thereafter, a number of catalytic ions (e.g., Pd²⁺) bind with those amino-functional molecules 70 that are not covered by monolayer 65.

Once the catalytic ions bond to some of amino-functional molecules 70, layer 60 is soaked, rinsed, bathed or immersed in an electroless bath. The electroless bath solution comprises metal ions, such as nickel, gold, palladium or a combination thereof, within a reducing agent and an inhibitor. The electroless bath facilitates the formation of second electrode 75. More particularly, the bonded catalytic ions act as nucleation sites for the growth of second electrode 75. In this regard, the nucleation sites reduce the catalytic ions bonds, enabling the metal ions from the electroless bath to grow into second electrode 75. As a consequence of the configuration of device 50 using the sequence of process steps detailed hereinabove, second electrode 75 is spaced from first electrode 55 by the length of one of monolayers 65.

Referring to FIG. 4, a flow chart 100 is depicted of a method of making an apparatus according to the principles of the present invention. Prior to performing the first step of the flow chart 100, a base, layer or substrate is provided. Depending on the functionality of the apparatus, the substrate may comprise a silicon or silicon dioxide, for example.

Initially, a first element is formed on the substrate. This forming step (110) may be performed by various means including depositing a layer of material and patterning the layer to form the desired size and shape of the first element. The first element, as stated hereinabove, may comprise a conductive component, an insulative component, a semiconductive component, or a nanotechnology component, such as a micro-electromechancial system (“MEMS”) device.

Thereafter, the substrate is soaked, rinsed, bathed or immersed in a solution. This soaking step (120) involves exposing the substrate, and more particularly the surfaces of the first element, to a solution that may comprise at least one organic molecule and an interfacial component. The one or more organic molecules may be realized by a self-assembled organic insulating molecule. In one example, the organic solution comprises alkanethiol. By this step, each organic insulating molecule bonds with the first element by means of one interfacial component.

Once the one or more self-assembled organic molecules are bonded to the first element, a second element may be formed. This forming step (130) may involve various known steps including evaporating a metal or depositing an insulating film, for example. Here, the one or more self-assembled organic molecules repel the formation of the second element onto the first element, thereby causing the second element to be formed at a distance from the first element of about the length of the self-assembled organic molecule—less that about 15 nm.

It should be noted that additional steps might be executed prior to forming the second element. For example, at least one attaching layer may be formed on the substrate. This attaching layer is formed adjacent to the self-assembled organic molecule on portions of the substrate not covered by the self-assembled organic molecule. By this step, the attaching layer supports the formation of the second element by defining its location on portion of the substrate not covered by the one or more self-assembled organic molecules. It should be noted that the attaching layer might also conductively couple the subsequently formed second element with the substrate.

Referring to FIG. 5, a flow chart 200 is depicted of a method of making a semiconductor device according to the principles of the present invention. The semiconductor device may advantageously be a FET, though other devices including, for example, a BJT, are also contemplated hereby. Prior to performing the first step of the flow chart 200, a layer or substrate of semiconductor material is provided.

Initially, a first electrode is formed on the semiconductor substrate. This forming step (210) may be performed by various means including evaporating a metal, such as gold, or doping a deposited silicon layer. Subsequently, the evaporated metal or doped deposited silicon layer is patterned to realize the desire size and shape of the first electrode.

Thereafter, the substrate is soaked, rinsed, bathed or immersed in a solution. This soaking step (220) involves exposing the substrate, and more particularly the surfaces of the first electrode, to a solution that may comprise at least one organic insulating molecule and an interfacial component. The one or more organic molecules may be self-assembled. In one example, the organic solution comprises alkanethiol. By this step, each organic insulating molecule bonds with the first electrode by means of one interfacial component and covers the channel of the FET from subsequent processing steps. While acting as a spacer, the one or more organic insulating molecules may also increase the breakdown voltage of the resultant FET.

Once the one or more self-assembled organic molecules are bonded to the first electrode, a second electrode may be formed. This forming step (230) may involve various known steps including evaporating a metal, such as gold, or doping a deposited silicon layer. Here, the one or more self-assembled organic molecules repel the formation of the second electrode onto the first electrode. Consequently, the second electrode is formed at a distance from the first electrode of about the length of one of the self-assembled organic molecules—less that about 15 nm. In one example, the length of one of the self-assembled organic molecules, and thusly, the distance spacing the first electrode from the second electrode, as well as the width of the channel is about two (2) nm.

Optionally, at least one attaching layer may be formed on the substrate prior to forming the second electrode. This attaching layer is formed adjacent to the one or more self-assembled organic insulating molecules—e.g., on portions of the substrate not covered by the one or more self-assembled organic molecules. By this step, the attaching layer supports the formation of the second electrode by defining its location on portion of the substrate not covered by the one or more self-assembled organic molecules. It should be noted that the attaching layer, here, conductively couples the second electrode with the substrate.

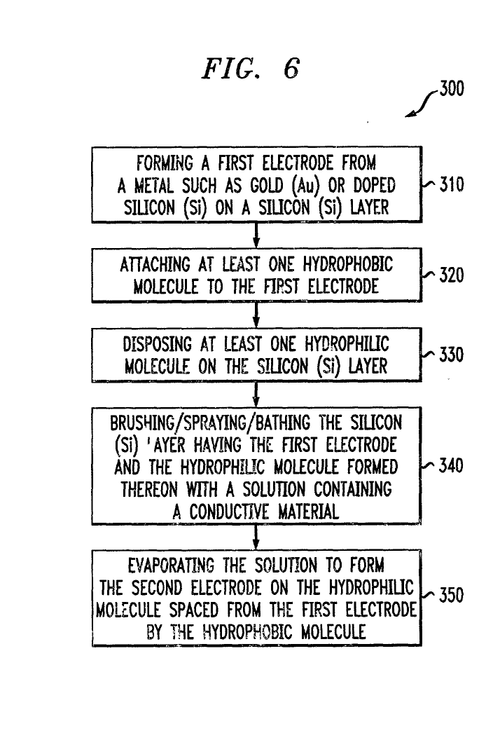

Referring to FIG. 6, a flow chart 300 is depicted of a method of making a transistor according to the principles of the present invention. According to this method, the transistor may advantageously be a FET, though other devices including, for example, a BJT, are also contemplated hereby. Prior to performing the first step of the flow chart 300, a semiconductor substrate, such as a silicon layer, is provided.

Initially, a first electrode is formed on the silicon layer. This forming step (310) may be performed by various means including evaporating a metal, such as gold, or doping a deposited silicon layer. Subsequently, the evaporated metal or doped deposited silicon layer is patterned to realize the desire size and shape of the first electrode.

Thereafter, at least one hydrophobic insulating molecule is attached to the first electrode. This attaching step (320) involves soaking, rinsing, bathing or immersing the silicon layer, and more particularly the surfaces of the first electrode, in a solution that comprises organic insulating molecules and interfacial components. The one or more organic insulating molecules may be self-assembled. In one example, the solution comprises alkanethiol. By this step, each organic insulating molecule bonds with the first electrode by means of one interfacial component and covers the channel of the FET from subsequent processing steps. While acting as a spacer, the one or more organic insulating molecules may also increase the breakdown voltage of the resultant FET.

Once the one or more hydrophobic insulating molecules are bonded to the first electrode, at least one hydrophilic molecule is disposed on the silicon layer. By this disposing step (330), the silicon layer is soaked, rinsed, bathed or immersed in a reactive solution comprising hydrophilic molecules. By disposing the one or more hydrophilic molecules on the silicon layer, an attaching layer may be formed. It will be apparent to skilled artisans that disposing the one or more hydrophilic molecules may be advantageously performed after the one or more hydrophobic insulating molecules are bonded to the first electrode. However, the reverse sequence of steps—attaching the one or more hydrophobic insulating molecules to the first electrode after the one or more hydrophilic molecules are disposed on the silicon layer having the first electrode thereon—is also contemplated by the present disclosure.

Subsequently, the silicon layer is exposed to a solution comprising a conductive material. By this exposing step (340), the silicon layer is brushed, sprayed or bathed with a dry solvent, such as conductive ink, for example. The conductive ink interacts with the one or more hydrophobic molecules and one or more hydrophilic molecules. More particularly, the conductive ink is repelled away by the one or more hydrophobic molecules covering the first electrode and the channel, and attracted to the one or more hydrophilic molecules of the attaching layer.

The conductive ink is then evaporated from the silicon layer. By this evaporating step (350), the second electrode is formed on the one or more hydrophilic molecules of the attaching layer. The second electrode is spaced from the first electrode by the length of the one or more hydrophobic molecules covering the first electrode and the channel, which repelled the conductive ink.

It should be noted that one or more hydrophilic molecules of the attaching layer have conductive properties for conductively coupling the silicon layer with second electrode. Moreover, the attaching layer also insures that the conductive ink need not cover the entire surface of the silicon layer. Thusly, upon completing the fabrication of the transistor, a removal step for removing excess conductive ink may not be necessary. Without such a removal step, the one or more hydrophobic molecules may be substantially short enough to space first and second electrodes in extremely close proximity to one another—less that about 15 nm. In one example, the length of the one or more hydrophobic molecules is about two (2) nm.

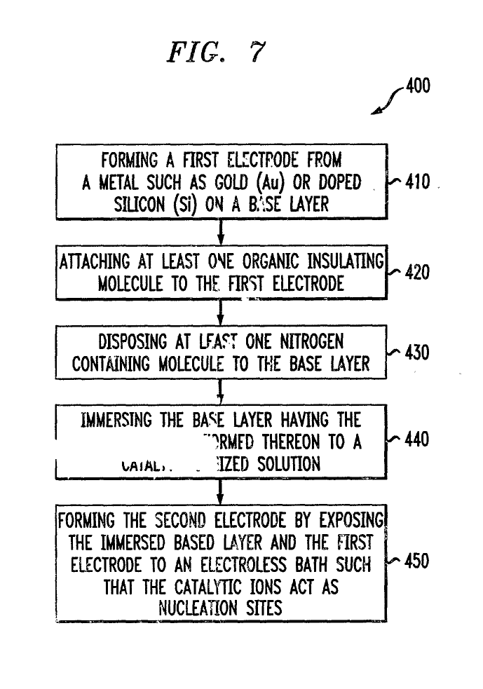

Referring to FIG. 7, a flow chart 400 is depicted another method of making a transistor according to the principles of the present invention. Here, the transistor may advantageously be a FET, though other devices including, for example, a BJT, are also contemplated hereby. Prior to performing the first step of the flow chart 400, a semiconductor substrate, such as a silicon base layer, is provided.

Initially, a first electrode is formed on the silicon layer. This forming step (410) may be performed by various means including evaporating a metal, such as gold, or doping a deposited silicon layer. Subsequently, the evaporated metal or doped deposited silicon layer is patterned to realize the desire size and shape of the first electrode.

Thereafter, at least one organic insulating molecule is attached to the first electrode. This attaching step (420) involves soaking, rinsing, bathing or immersing the silicon layer, and more particularly the surfaces of the first electrode, in a solution that may comprise organic insulating molecules and interfacial components. The one or more organic insulating molecules may be self-assembled. In one example, the solution comprises alkanethiol. By this step, each organic insulating molecule bonds with the first electrode by means of one interfacial component and covers the channel of the FET from subsequent processing steps. While acting as a spacer, the one or more organic insulating molecules may also increase the breakdown voltage of the resultant FET.

Once the one or more organic insulating molecules are bonded to the first electrode, at least one amino-functional molecule is disposed on the silicon layer. This disposing step (430) advantageously involves exposing the silicon layer to a vapor phase solution comprising at least one chelating, nitrogen-containing molecule. In the alternative, disposing step (430) involves soaking, rinsing, bathing or immersing the silicon layer in a solution comprising at least one chelating, nitrogen-containing molecule. By disposing the one or more amino-functional molecules on the silicon layer, an attaching layer may be formed. It will be apparent to skilled artisans that disposing the one or more amino-functional molecules may be advantageously performed after the one or more organic insulating molecules are bonded to the first electrode. However, the reverse sequence of steps—attaching the one or more organic insulating molecules to the first electrode after the one or more amino-functional molecules are disposed on the silicon layer having the first electrode thereon—is also contemplated by the present disclosure.

Subsequently, the silicon layer is exposed to a solution comprising a conductive material. By this step (440), the silicon layer is soaked, rinsed, bathed or immersed in a catalytic ionized solution. In one example, the catalytic ionized solution comprises catalytic ions, such as Pd²⁺, for example, within hydrochloric acid. As a result, a number of catalytic ions (e.g., Pd²⁺) bind with a number of amino-functional molecules on the silicon layer that are not covered by the one or more organic insulating molecules.

A nucleating metal deposition step is then performed on the previously immersed silicon layer. Here, the previously immersed silicon layer may be exposed to an electroless bath. By this exposing step (450), the electroless solution causes the catalytic ions from the catalytic ionized solution to act as nucleation sites for the formation of the second electrode. A second electrode, as such, is formed on the number of amino-functional molecules not covered by the one or more organic insulating molecules. Consequently, the second electrode is grown at a distance from the first electrode of about the length of the one or more organic insulating molecules, given the positioning of the number of amino-functional molecules on the silicon layer not covered by the one or more organic insulating molecules.

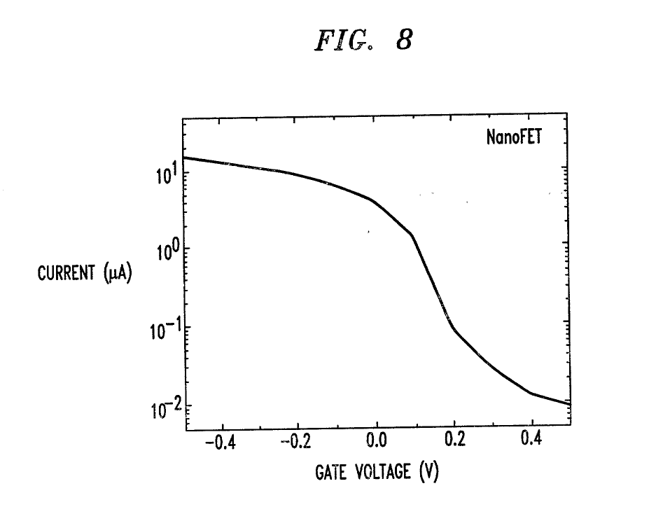

Referring to FIG. 8, a graphical illustration of a first set of characteristics of an exemplary FET employing the principles of the present invention is shown. More particularly, the graphical illustration depicts the drain current (μA) versus drain voltage (V) characteristics of such an FET at room temperature having a channel length, as defined by an alkanethiol layer spacing the drain electrode from the source electrode, of about 2 nm.

While the particular invention has been described with reference to illustrative embodiments, this description is not meant to be construed in a limiting sense. It is understood that although the present invention has been described, various modifications of the illustrative embodiments, as well as additional embodiments of the invention, will be apparent to one of ordinary skill in the art upon reference to this description without departing from the spirit of the invention, as recited in the claims appended hereto. It is therefore contemplated that the appended claims will cover any such modifications or embodiments as fall within the true scope of the invention.

1. An apparatus comprising:
a first and a second element; and
at least one monolayer for repelling the formation of the second element on the first element and for spacing the second element from the first element at about a length of the at least one monolayer.

2. The apparatus of claim 1, wherein the at least one monolayer increases a breakdown characteristic of the apparatus.

3. The apparatus of claim 2, wherein the at least one monolayer attaches to the first element and the length is less than about 15 nanometers.

4. The apparatus of claim 3, further comprising at least one attaching layer for supporting the formation and defining a location for the second element on the substrate, the at least one attaching layer adjacent to the at least one monolayer.

5. The apparatus of claim 4, wherein one of the at least one monolayer and the at least one attaching layer comprises hydrophobic properties and the other of the at least one monolayer and the at least one attaching layer comprises hydrophilic properties.

6. The apparatus of claim 5, wherein the at least one attaching layer conductively couples the second element with the substrate.

7. The apparatus of claim 1, wherein the first and second elements are disposed on a substrate, and the first element comprises a conductive component, a semiconductive component, an insulative component or a MEMS component, and the second element comprises a conductive component, a semiconductive component, an insulative layer or a MEMS component.

8. The apparatus of claim 1, wherein the at least one monolayer comprises at least one self-assembled organic insulating molecule.

9. The apparatus of claim 8, wherein the at least one self-assembled organic insulating molecule comprises alkyl chain.

10. A transistor comprising:
a first and a second electrode formed on a substrate;
an attaching layer for conductively coupling the second electrode with the substrate; and
at least one self-assembled monolayer for repelling the formation of the second electrode and the attaching layer on the first electrode, wherein the second electrode is spaced from the first electrode by about a length of the self-assembled monolayer.

11. The transistor of claim 10, wherein the at least one self-assembled monolayer insulates the first electrode from the second electrode, thereby increasing the voltage breakdown characteristics of the transistor.

12. The transistor of claim 11, wherein the first component repels the formation of the second electrode on an active channel, the attaching layer disposed adjacent to the active channel and attached to the second electrode.

13. The transistor of claim 12, wherein the at least one self-assembled monolayer comprises hydrophobic properties, and the attaching layer comprises hydrophilic properties.

14. The transistor of claim 11, wherein the at least one monolayer comprises at least one organic insulating molecule.

15. The transistor of claim 14, wherein the at least one organic insulating molecule comprises alkyl chain.

16. The transistor of claim 10, wherein the length of the monolayer is less than 15 nanometers.

17. A method comprising:
forming a first electrode on a semiconductor substrate having an active channel;
attaching at least one self-assembled monolayer to the first electrode, the at least one self-assembled monolayer covering the active channel;
forming an attaching layer on the semiconductor substrate adjacent to the at least one self-assembled monolayer; and
forming a second electrode on the attaching layer and spaced from the first electrode by the at least one self-assembled monolayer.

18. The method of claim 17, wherein the attaching layer comprises at least one conductive hydrophilic molecule, and the step of attaching the at least one self-assembled monolayer further comprises soaking the semiconductor substrate in a solution of at least one hydrophobic molecule.

19. The method of claim 18, wherein the at least one hydrophobic molecule comprises an organic insulating molecule.

20. The method of claim 19, wherein the organic insulating molecule comprises alkyl chain.

21. The method of claim 17, wherein the conductive hydrophilic molecule comprises nitrogen.

22. The method of claim 17, wherein the step of forming a second electrode further comprises performing an electroless deposition.

23. The method of claim 17, wherein the step of forming a second electrode further comprises performing a nucleating metal deposition on a portion of the attaching layer.

24. A method comprising:
attaching at least one self-assembled monolayer to a first element formed on a substrate;
forming at least one attaching layer on the substrate and adjacent to the at least one self-assembled monolayer; and
forming a second element on the at least one attaching layer spaced from the first element by about a length of the at least one self-assembled monolayer.

25. The method of claim 24, wherein the at least one self-assembled monolayer repels the formation of the second element and the at least one attaching layer on the first element, and spaces the second element from the first element.

26. The method of claim 25, the first element comprises a conductive component, a semiconductive component, an insulative component or a MEMS component, and the second element comprises a conductive component, a semiconductive component, an insulative component or a MEMS component.

27. The method of claim 25, wherein the step of attaching at least one self-assembled monolayer further comprises soaking the first element and the substrate with a first solution comprising at least one organic insulating molecule.

28. The method of claim 27, wherein the at least one organic insulating molecule comprises alkyl chain.

29. The method of claim 27, wherein the at least one attaching layer conductively couples the second element with the substrate.

30. The method of claim 29, wherein the step of forming a second element further comprises evaporating a metal to form the second element.

31. The method of claim 30, wherein the at least one organic insulating molecule comprises hydrophobic properties, the at least one attaching layer comprises hydrophobic properties, and the step of forming a second element further comprises:
exposing the substrate having the at least one attaching layer formed thereon with a second solution comprising a conductive material; and
evaporating the solution to form the second element on the at least one attaching layer, thereby spacing the second element from the first element by the length of the at least one organic insulating molecule.

32. The method of claim 31, wherein the step of exposing the substrate comprises brushing, spraying or bathing a dry solvent onto the substrate having the at least one attaching layer.

33. The method of claim 32, wherein the dry solvent comprises conductive ink.

34. The method of claim 27, wherein the organic insulating molecule comprises hydrophobic properties, and the step of forming a second element further comprises:
disposing at least one nitrogen-containing molecule on the substrate;
exposing the substrate having the at least one nitrogen-containing molecule to a catalytic ionized solution; and
immersing the exposed substrate in an electroless solution to form the second element on the at least one nitrogen-containing molecule, thereby spacing the second element from the first element by the length of the at least one organic insulating molecule.

35. The method of claim 34, wherein the step of immersing the exposed substrate in an electroless solution causes catalytic ions from the catalytic ionized solution to act as nucleation sites for the second element.
